(19) United States
(12) Patent Application Publication
(10) Pub. No.: US 2024/0105573 A1
(43) Pub. Date: Mar. 28, 2024

(54) POWER MODULE FOR VEHICLE AND METHOD OF MANUFACTURING THE SAME

(71) Applicants: Hyundai Motor Company, Seoul (KR); Kia Corporation, Seoul (KR)

(72) Inventors: Jun Hee PARK, Hwaseong-Si (KR); Sung Taek Hwang, Seoul (KR); Nam Sik Kong, Hwaseong-Si (KR); Myung III You, Gwangju (KR)

(21) Appl. No.: 18/220,134

(22) Filed: Jul. 10, 2023

(30) Foreign Application Priority Data
Sep. 26, 2022 (KR) 10-2022-0121623

(51) Int. Cl. H01L 23/498; H01L 21/48; H01L 23/00

(52) U.S. Cl. CPC H01L 23/49833; H01L 21/4867; H01L 24/32; H01L 24/33; H01L 24/48; H01L 24/73; H01L 2224/32238; H01L 2224/33181; H01L 2224/48091; H01L 2224/48105; H01L 2224/48175; H01L 2224/73215; H01L 2224/73265

(57) ABSTRACT

A power module for a vehicle, includes: a first substrate including a first metal circuit disposed on a 1-1st surface, and a first spacer extending from the first metal circuit in a first direction; a second substrate spaced from and facing the first substrate in a second direction, and including a second metal circuit disposed on a 2-1st surface facing the 1-1st surface, and a second spacer extending from the second metal circuit in the second direction; and a semiconductor chip disposed between the first substrate and the second substrate, the first spacer and the second spacer extending toward each other.

### CROSS REFERENCE TO RELATED APPLICATION

The present application claims priority to Korean Patent Application No. 10-2022-0121623, filed Sep. 26, 2022, the entire contents of which is incorporated herein for all purposes by this reference.

### BACKGROUND OF THE PRESENT DISCLOSURE

### Field of the Present Disclosure

The present disclosure relates to a power module for a vehicle, and particularly to a power module for a vehicle, which is mounted to an inverter for operating a driving motor provided in an electric vehicle.

### Description of Related Art

As one among the key components of hybrid electric vehicles and electric vehicles, there is a power converter (for example, an inverter). The power converter is a major component of an eco-friendly vehicle, and many technologies for the power converter have been developed. The key technology in the field of eco-friendly vehicles is to develop a power module which is a core portion of the power converter and accounts for the highest costs.

Among such power modules, there is a double-sided cooling power module in which two surfaces corresponding to different substrates and facing each other are cooled individually. The double-sided cooling power module employs a via spacer to connect the different substrates and secure a space between the different substrates, and it is important where to place the via spacer due to its function of electric conduction. Furthermore, it is important to secure the durability of the via spacer.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a double-sided cooling power module in which an upper substrate and a lower substrate are connected by a spacer formed integrally with metal circuits of the upper and lower substrates and extending from the metal circuits in a direction where the upper and lower substrates face each other.

According to an exemplary embodiment of the present disclosure, there is provided a power module for a vehicle, including: a first substrate including a first metal circuit disposed on a 1-1st surface, and a first spacer extending from the first metal circuit in a first direction thereof; a second substrate spaced from and facing the first substrate in a second direction, and including a second metal circuit disposed on a 2-1st surface facing the 1-1st surface, and a second spacer extending from the second metal circuit in the second direction thereof; and a semiconductor chip disposed between the first substrate and the second substrate, wherein the first spacer and the second spacer are extended toward each other.

The semiconductor chip may include a first surface connected to the second spacer, and a second surface opposite to the first surface and connected to the first metal circuit.

The first spacer and the second spacer may be electrically connected to each other for electric connection between the first substrate and the second substrate.

The first spacer and the second spacer may include glass frit in an internal portions thereof except end portions thereof.

The spacer may be extended from the metal circuit by printing and curing a conductive paste through a screen or by curing a conductive molten material.

When the spacer is provided using a screen, a deformed portion of a conductive paste stretched in the direction of releasing the screen in a screen releasing process may be post-processed by a pressing process or a grinding process.

A cooling layer connected to a cooler may be disposed on each of a 1-2nd surface opposite to the 1-1st surface of the first substrate and a 2-2nd surface opposite to the 2-1st surface of the second substrate.

The power module may further include a signal lead connected to the first surface of the semiconductor chip by wire bonding.

The second metal circuit may be set to have a preset first thickness, and the second spacer may be set to have a second thickness thicker than the first thickness based on the height of the wire bonding connected to the semiconductor chip.

At least two among the semiconductor chip, the first substrate, and the second substrate may be connected to each other by a bonding process including soldering or sintering.

The power module may further include a power lead disposed between the first metal circuit and the second metal circuit.

According to an exemplary embodiment of the present disclosure, there is provided a method of manufacturing a power module, including: forming a metal circuit on a first surface of an insulating layer; and forming a plurality of spacers extending from the metal circuit in a certain direction, the forming of the plurality of spacers including: printing a conductive paste; and curing the printed conductive paste, and the printing and the curing being repeated a plurality of times.

The printing may include: seating a screen formed with a pattern; applying the conductive paste to the pattern; releasing the screen; and removing a deformed portion of the applied conductive paste stretched as the screen is released.

The method may further include forming a cooling layer on a second surface of the insulating layer opposite to the first surface of the insulating layer.

The method may further include plating the metal circuit and the plurality of spacers.

According to an exemplary embodiment of the present disclosure, the spacers integrally formed extending from the metal circuits of the upper substrate and the lower substrate toward each other are used in connecting the upper substrate and the lower substrate, and therefore the upper substrate and the lower substrate are connected without adding the separate via spacer or spacer parts for connecting the upper substrate and the lower substrate, having effects on simplifying the process and reducing manufacturing costs due to decrease in the number of parts.

Furthermore, the spacer is formed integrally and not separated, and it is thus possible to accurately control the position of the spacer.

Furthermore, the substrate and the spacer are formed as a single body, and therefore the tolerance for the error of the single body required to be compensated by soldering becomes narrower than those for individual thickness errors of the substrate and the spacer in the case of using the separate spacer.

Furthermore, when the spacer is formed by stacking copper pastes, the spacer exhibits higher heat dissipation performance due to the thermal conductivity of copper, improving thermal characteristics.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a lateral cross-sectional view of a power module for a vehicle according to an exemplary embodiment of the present disclosure, and

FIG. 2 and FIG. 3 are views showing a procedure of manufacturing a lower substrate (or upper substrate) of a power module for a vehicle according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to a same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Because the embodiments of the present disclosure may be variously modified and have various forms, specific exemplary embodiments will be illustrated in the drawings and described in detail in the present specification or application. However, it may be understood that embodiments of the present disclosure are intended not to be limited to the specific embodiments but to cover all modifications, equivalents or alternatives without departing from the spirit and technical scope of the present disclosure.

Terms such as “first” and/or “second” are used herein merely to describe a variety of elements, but the elements are not limited by these terms. Such terms are used only for distinguishing one element from another element. For example, without departing from the conceptual scope of the present disclosure, a first element may be referred to as a second, and vice versa.

When a certain element is referred to as being “connected to” or “coupled to” another element, it will be understood that they may be directly connected to or coupled to each other but or intervening elements may be present therebetween. On the other hand, when a certain element is referred to as being “directly connected to” or “directly coupled to” another element, it will be understood that no intervening elements are present therebetween. Other expressions describing relationships between elements, such as “between,” “immediately between,” “adjacent to,” “directly adjacent to,” or etc. may also be construed in the same manner.

Terms used in the present specification are merely used for explaining specific embodiments, but not intended to limit the present disclosure. Unless the context clearly dictates otherwise, singular forms include plural forms as well. It is to be understood that terms “include,” “have,” etc. As used herein specify the presence of stated features, integers, steps, operations, elements, components, or combination thereof, but do not preclude the presence or addition of one or more other features, integers, steps, operations, elements, components or combination thereof.

Unless defined otherwise, all terms used herein including technical or scientific terms have the same meanings as those generally understood by a person having ordinary knowledge in the art to which the present disclosure pertains. The terms such as those defined in generally used dictionaries are construed to have meanings matching that in the context of related technology, and unless clearly defined otherwise, are not construed to be ideally or excessively formal.

In general, a double-sided cooling power module requires electrical connection between a second substrate and a first substrate for circuit configuration. To the present end, a via spacer provided separately from the second and first substrates may be used. Furthermore, the circuit configuration of the power module and the arrangement of other parts are generally varied in accordance with the positions of the via spacer. Furthermore, the size of the via spacer needs to be large to conduct a high current according to the characteristics of the power module using high power, and therefore there is a limit to reduce the size of the via spacer.

Meanwhile, the double-sided cooling power module generates a large amount of heat during operation due to the structure of internal chips disposed inside the power module. Furthermore, when neighboring chips generate heat simultaneously during the operation of the power module, thermal overlap effects between the chips cause the power module to additionally increase in temperature. The spacer is generally bonded by a bonding material to maintain the electrical connection between the upper substrate and the lower substrate, and a metal layer applied to a semiconductor chip is consumed while reacting with the bonding material due to the thermal overlap effects or the like heat, decreasing the durability (or life) or deteriorating electrical characteristics. Furthermore, the via spacer may be titled by external shock or vibration while the liquid bonding material is solidified, and thus causes a problem that the second substrate and the first substrate are not normally connected.

According to an exemplary embodiment of the present disclosure, a via processor formed integrally with the substrates is provided instead of the foregoing separate via spacer.

Below, the present disclosure will be described in detail by describing embodiments with reference to the accompanying drawings. Like reference numerals in the drawings refer to like numerals.

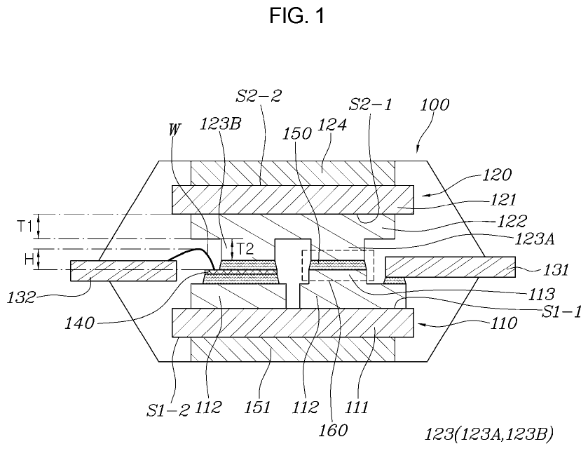

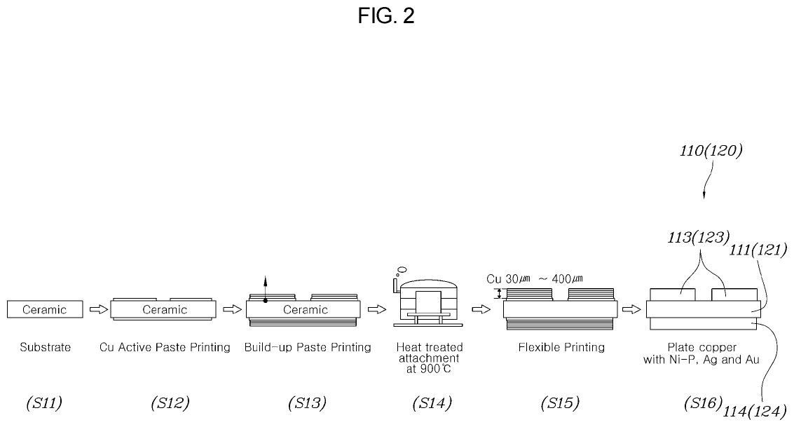

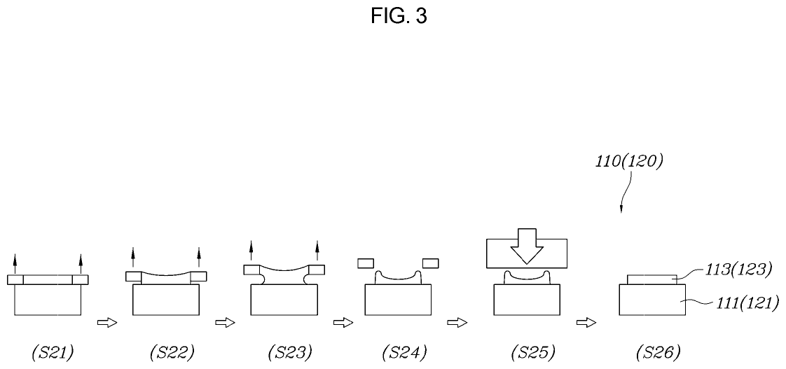

FIG. 1 is a lateral cross-sectional view of a power module for a vehicle according to an exemplary embodiment of the present disclosure, and FIG. 2 and FIG. 3 are views showing a procedure of manufacturing a lower substrate (or upper substrate) of a power module for a vehicle according to an exemplary embodiment of the present disclosure.

Embodiments of the power module 100 for the vehicle according to an exemplary embodiment of the present disclosure will be described with reference to FIG. 1, FIG. 2, and FIG. 3.

The power module 100 for the vehicle according to an exemplary embodiment of the present disclosure includes a first substrate 110, a second substrate 120 spaced from the first substrate 110 in a vertical direction and facing the first substrate 110, a semiconductor chip 140 disposed between the second substrate 120 and the first substrate 110, a power lead 131 connected to the first substrate 110 or the second substrate 120, and a signal lead 132 connected to the semiconductor chip 140.

As shown in FIG. 1 and FIG. 2, the first substrate 110 may include a first insulating layer 111, a first cooling layer 114 disposed on a 1-2nd surface S1-2nd of the first insulating layer 111, a first metal circuit 112 disposed on a 1-1st surface S1-1st of the first insulating layer 111, and a first spacer 113 extending upwards from the first metal circuit 112 and formed integrally with the first metal circuit 112.

The first insulating layer 111 generally includes a polymer resin and has a plate shape. The first cooling layer 114 is in contact with a cooling channel on the bottom thereof and functions to transfer heat generated from the inside of the double-sided cooling power module 100 to the cooling channel. The first metal circuit 112 refers to an electric path which is generally made of copper or the like conductor having predetermined electrical conductivity, is formed on the 1-1st surface S1-1st of the first insulating layer 111, and allows an electric current to flow as connected to the power lead 131. The semiconductor chip 140 may be electrically connected to the first metal circuit 112.

The first spacer 113 is formed extending upwards from the first metal circuit 112 made of copper so that the first spacer 113 and the first metal circuit 112 may be formed as a single body, allowing current flowing from the power lead 131 to the first metal circuit 112 to flow to the first spacer 113.

As shown in FIG. 1, FIG. 2, and FIG. 3, the second substrate 120 may have a structure similar to that of the first substrate 110. The second substrate 120 may include a second insulating layer 121, a second cooling layer 124 formed on a 2-2nd surface S2-2nd of the second insulating layer 121, a second metal circuit 122 disposed on a 2-1st surface S2-1st of the second insulating layer 121, and a second spacer 123 extending downwards from the second metal circuit 122 and formed integrally with the second metal circuit 122.

Like the first insulating layer 111, the second insulating layer 121 generally includes a polymer resin and has a plate shape. Like the first cooling layer 114, the second cooling layer 124 is in contact with a cooling channel on the top thereof and functions to transfer heat generated from the inside of the double-sided cooling power module 100 to the cooling channel. The second metal circuit 122 refers to an electric path which is generally made of copper or the like conductor having high electrical conductivity, and is formed on the 2-1st surface S2-1st of the second insulating layer 121.

The semiconductor chip 140 is disposed between and electrically connected to a second spacer 123B of the second substrate 120 and the first metal circuit 112 of the first substrate 110.

As shown in FIG. 1, the first substrate 110 is disposed at a lower side, the second substrate 120 is disposed at an upper side, and the first metal circuit 112 and the second metal circuit 122 are assembled to face each other. Between the first substrate 110 and the second substrate 120, there may be disposed the semiconductor chip 140, the signal lead 132, and the power lead 131.

The power lead 131 may be connected to the first metal circuit by soldering, and the signal lead 132 may be connected to the top portion of the semiconductor chip 140 by wire bonding W.

Below, the spacer will be described in more detail.

As shown in FIG. 1, the first spacer 113 extending from the first substrate 110 toward the second substrate 120 and a second spacer 123A extending from the second substrate 120 toward the first substrate 110 may be connected to each other to form a via spacer 160.

The first spacer 113 and the second spacer 123A are connected to each other so that the first metal circuit 112 and the second metal circuit 122 can electrically conduct with each other. Through the power lead 132 connected to at least one of the first metal circuit 112 and the second metal circuit 122, current flows in the corresponding metal circuit.

With the present structure, the first spacer 113 and a second spacer 123 are connected forming the via spacer 160, and therefore there are no needs of forming the conventional separate via spacer, reducing manufacturing costs.

Furthermore, when the first metal circuit and the second metal circuit are connected by the conventional separate via spacer, opposite longitudinal end portions of the via space are individually subjected to soldering or the like bonding process. On the other hand, according to an exemplary embodiment of the present disclosure, the first spacer 113 and the second spacer are connected by soldering 150 formed in one bonding process, simplifying the manufacturing process and reducing the manufacturing costs.

Furthermore, the conventional separate via spacer may be titled while the liquid soldering is solidified during in the bonding process for the conventional separate via spacer. On the other hand, according to an exemplary embodiment of the present disclosure, the first spacer 113 and the second spacer 123A are formed integrally with the circuit substrates, respectively, preventing the via spacer 160 from being tilted.

The second metal circuit 122 may be set to have a preset first thickness T1, and the second spacer 123B may be set to have a second thickness T2 thicker than the first thickness T1 based on the height H of the wire bonding W connected to the semiconductor chip 140. Therefore, the second metal circuit 122 and the spacer 123A or 123B according to an exemplary embodiment are formed as a single body. When the circuit substrate 122 and the spacer 123A or 123B are considered as a single metal layer, it may be regarded that the metal layer includes two or more layers different in height.

As shown in FIG. 1, the second metal circuit 122 is electrically connected to the semiconductor chip 140 or a lead frame 130 through the second spacer 123. For the present electrical connection, the second metal circuit 122 may be set to have the first thickness in consideration of current allowable capacity. When the wire bonding W connected to the signal lead 132 is present, the second spacer 123 extending from the second metal circuit 122 may be set to have a thickness varied depending on the height H of the wire bonding W. The second spacer 123B may be set to have the second thickness T2 thicker than the first thickness T1.

In general, the first thickness T1 of the second metal circuit 122 may be 0.3 mm in consideration of the current allowable capacity, and may range from 0.1 to 0.8 mm as necessary. Furthermore, the second thickness T2 of the second spacer 123B extending from the second metal circuit 122 and connected to the semiconductor chip 140 may generally be about 1.0 mm in consideration of the height H of the wire bonding W.

At least two among the semiconductor chip 140, the first substrate 110, and the second substrate 120 may be connected to each other by the bonding process including soldering or sintering.

One surface of the semiconductor chip 140 is bonded and connected to the first metal circuit 112 by soldering or sintering, and the second spacer 123 extending from the second substrate 120 is bonded and connected to the other surface of the semiconductor chip 140 or the first spacer 113 extending from the first metal circuit 112 by the soldering or the sintering, so that the first metal circuit 112 and the second metal circuit 122 may be electrically connected to each other forming the via spacer 160.

The first spacer 113 and the second spacer 123 may include glass frit in their internal portions except their end portions.

The glass frit refers to an additive added for bonding metal to ceramic at a low temperature and forms physical/chemical bonding as a material having glass phase penetrates into the ceramic. The glass frit mainly includes SiO₂, and pure SiO₂ has a coefficient of thermal expansion (CTE) of 8.1 ppm, which is considerably lower than that of metal.

When the first spacer 113 and the second spacer 123 are stacked, the present stacked structure is configured to relieve the stress caused by the thermal expansion of the glass frit contained in the metal layer. Thus, the present stacked structure is applicable to the first spacer 113 and the second spacer 123 between which a CTE mismatch is required to be considered.

On the other hand, the end portions of the first spacer 113 and the second spacer 123 in the extending direction (for example, the upper portion of the first spacer 113 of the first substrate 110 or the lower portion of the second spacer 123 of the second substrate 120) may be in contact with the semiconductor chip 140 or subjected to the soldering 150. Therefore, the end portions do not include the glass frit in consideration of the electric bonding based on the bonding material.

As shown in FIG. 1, the first spacer 113 and the second spacer 123 respectively extend from the first metal circuit 112 and the second metal circuit 122 and face each other. To extend the first spacer 113 and the second spacer 123 from the first metal circuit 112 and the second metal circuit 122, respectively, various printing methods such as screen printing and 3D printing may be used.

FIG. 2 and FIG. 3 are views showing a procedure of manufacturing the first substrate 110 and the second substrate 120 of a power module for a vehicle according to an exemplary embodiment of the present disclosure.

As shown in FIG. 2, to extend the first spacer 113 or the second spacer 123 from the first metal circuit 112 or the second metal circuit 122, the insulating layer is prepared (S11), and the metal layer is printed to form the metal circuit 112 or 122 (S12). After the process S12 of forming the metal circuit 112 or 122, a conductive paste is printed through a screen (S13) and then thermally cured (S14). The printing process S13 and the thermal curing process S14 are repeated to form the first spacer 113 or the second spacer 123 (S15). Accordingly, the metal circuit 112 or 122 is plated with nickel-phosphorus alloy, silver, gold, etc. (S16), forming the first substrate 110 or the second substrate 120.

In the case where the first spacer 113 and the second spacer 123 are formed by the screen printing, the edge portions of the paste being in contact with the screen may be stretched in a direction of releasing the screen due to the viscosity of the paste in a screen releasing process in which the screen is removed from the printed paste. The deformed portions of the stretched paste may be post-processed by a pressing process or a grinding process. Below, the screen releasing process and the post-processing procedure will be described with reference to FIG. 3.

FIG. 3 is a view showing the screen releasing process and the post-processing procedure.

As shown in FIG. 3, the deformed portions (DE) formed as the conductive paste is stretched in the screen releasing process may be removed by pressing, grinding, etc. Here, the deformed portions (DE) have a cross-sectional shape in which the edge portions are raised, and thus will be called a ‘dog ear.’

Referring to FIG. 3, the conductive paste is printed while the screen is accommodated on the substrate (S21), and the screen is then released from the substrate (S22 and S22). In the instant case, the conductive paste being in contact with the screen is stretched forming the dog ear (DE) as the screen is released from the substrate (S24), and thus a process of removing the dog ear (DE) is performed (S25). The process S25 of removing the dog ear (DE) may include the pressing process or the grinding process. When the dog ear (DE) is removed, the metal layer has a flat surface (S26).

By repeating the processes S21 to S26, the spacer 113 or 123 is precisely prepared having a thickness desired as requested by a designer.

Besides the screen printing, the 3D printing that forms a structure by curing a conductive molten material may be used to prepare the spacer 113 or 123. When the 3D printing is used to prepare the spacer 113 or 123, the spacer 113 or 123 is prepared to have a thickness requested by a designer at once, having an advantage that manufacturing time is shortened.

Referring to FIG. 2 and FIG. 3, a method of manufacturing a power module according to an exemplary embodiment of the present disclosure will be described.

The method of manufacturing the power module according to an exemplary embodiment of the present disclosure may include the steps of forming a metal circuit on a first surface of an insulating layer (S11); and forming a plurality of spacers extending in a first direction on the metal circuit (S12). The step S12 of forming the plurality of spacers may include the steps of printing a conductive paste (S13); and thermally curing the printed conductive paste. The printing step S13 and the thermal curing step S14 may be repeated a plurality of times.

Referring to FIG. 3, the printing step S13 may include the steps of seating a screen formed with a pattern; applying a conductive paste to the pattern; releasing the screen (S22, S23, and S24); and removing a deformed portion of the applied conductive paste stretched as the screen is released (S25).

After the step S25 of removing the deformed portion, the conductive paste may be completely patterned (S26).

Furthermore, the method of manufacturing the power module according to an exemplary embodiment of the present disclosure may include a step of forming a cooling layer on a second surface of the insulating layer opposite to the first surface (S15).

The method of manufacturing the power module according to an exemplary embodiment of the present disclosure may further include plating the metal circuit and the plurality of spacers (S16).

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module for a vehicle, the power module comprising:
a first substrate including a first metal circuit disposed on a first surface of the first substrate, and a first spacer extending from the first metal circuit in a first direction;
a second substrate spaced from and facing the first substrate of the first substrate in a second direction, and including a second metal circuit disposed on a first surface of the second substrate facing the first surface of the first substrate, and a second spacer extending from the second metal circuit in the second direction; and
a semiconductor chip disposed between the first substrate and the second substrate,
wherein the first spacer and the second spacer are extended toward each other.

2. The power module of claim 1, wherein the semiconductor chip includes a first surface connected to the second spacer, and a second surface opposite to the first surface of the semiconductor chip and connected to the first metal circuit.

3. The power module of claim 1, wherein the first spacer and the second spacer are electrically connected to each other for electric connection between the first substrate and the second substrate.

4. The power module of claim 3, wherein the first spacer and the second spacer include glass frit in internal portions thereof except end portions thereof.

5. The power module of claim 1, wherein the first spacer and the second spacer are extended from the first metal circuit and the second metal circuit, respectively by printing and curing a conductive paste through a screen or by curing a conductive molten material.

6. The power module of claim 1, wherein the first spacer and the second spacer prepared using a screen is post-processed by a pressing process or a grinding process with respect to a deformed portion of a conductive paste stretched in a direction of releasing the screen in a screen releasing process.

7. The power module of claim 1, further including a cooling layer connected to a cooler and disposed on each of a second surface of the first substrate opposite to the first surface of the first substrate and a second surface of the second substrate opposite to the first surface of the second substrate.

8. The power module of claim 1, further including a signal lead connected to a first surface of the semiconductor chip by wire bonding.

9. The power module of claim 8, wherein the second metal circuit has a preset first thickness, and the second spacer has a second thickness thicker than the first thickness based on a height of the wire bonding connected to the semiconductor chip.

10. The power module of claim 1, wherein at least two among the semiconductor chip, the first substrate, and the second substrate are connected to each other by a bonding process including soldering or sintering.

11. The power module of claim 1, further including a power lead disposed between the first metal circuit and the second metal circuit.

12. A power module for a vehicle, the power module comprising:
a first substrate including:
a first metal circuit disposed on a first surface of the first substrate; and
a first spacer extending from the first metal circuit in a first direction;
a second substrate spaced from and facing the first substrate of the first substrate in a second direction, and including:
a second metal circuit disposed on a first surface of the second substrate facing the first surface of the first substrate;
a second spacer extending from the second metal circuit in the second direction; and
an additional second spacer extending from the second metal circuit in the second direction;
a semiconductor chip disposed between the first substrate and the second substrate,
wherein the first spacer and the additional second spacer are extended toward each other.

13. The power module of claim 12, wherein the first spacer and the additional second spacer are electrically connected to each other by a bonding process including soldering or sintering for electric connection between the first substrate and the second substrate.

14. The power module of claim 12, wherein the first spacer, the second spacer and the additional second spacer include glass frit in internal portions thereof except end portions thereof.

15. The power module of claim 12, further including a cooling layer connected to a cooler and disposed on each of a second surface of the first substrate opposite to the first surface of the first substrate and a second surface of the second substrate opposite to the first surface of the second substrate.

16. The power module of claim 12, further including a signal lead connected to a first surface of the semiconductor chip by wire bonding,
wherein the second metal circuit has a preset first thickness, and the second spacer has a second thickness thicker than the first thickness based on a height of the wire bonding connected to the semiconductor chip.

17. A method of manufacturing a power module, the method comprising:
forming a metal circuit on a first surface of an insulating layer; and
forming a plurality of spacers extending from the metal circuit in a predetermined direction,
the forming of the plurality of spacers including:
printing a conductive paste; and
curing the printed conductive paste, and
wherein the printing and the curing are repeated predetermined times.

18. The method of claim 17, wherein the printing includes:
seating a screen formed with a pattern;
applying the conductive paste to the pattern;
releasing the screen; and
removing a deformed portion of the applied conductive paste stretched as the screen is released.

19. The method of claim 17, further including forming a cooling layer on a second surface of the insulating layer opposite to the first surface of the insulating layer.

20. The method of claim 17, further including plating the metal circuit and the plurality of spacers.
